(19) United States
(12) Patent Application Publication
(10) Pub. No.: US 2004/0061237 A1
(43) Pub. Date: Apr. 1, 2004

(54) Method of reducing voiding in copper interconnects with copper alloys in the seed layer

(75) Inventors: Larry Zhao, San Jose, CA (US); Paul R. Besser, Sunnyvale, CA (US); Connie Wang, Menlo Park, CA (US)

Correspondence Address: McDERMOTT, WILL & EMERY, 600 13th Street, N.W., Washington, DC, 20005-3096, US

(73) Assignee: Advanced Micro Devices, Inc.

(21) Appl. No.: 10/254,540

(22) Filed: Sep. 26, 2002

(51) Int. Cl. H01L 23/52

(52) U.S. Cl. 257/762

(57) ABSTRACT

A method for forming a copper interconnect with improved via integrity and elimination of via voiding employs a copper seed layer having an alloy element within the seed layer. The alloy element increases the resistance of the copper seed layer to acidic plating chemistry as the vias are filled and as the pulse-reverse wave form is initiated in the electrochemical plating process. The prevention of void formations at the bottom of the via improves the copper filling, with resulting improved electromigration performance, reduced via resistance and improved product speed.

### FIELD OF THE INVENTION

The present invention relates to the field of semiconductor processing, and more particularly, to reduction of electromigration voids in metal interconnect structures.

### BACKGROUND OF THE INVENTION

The escalating requirements for high density and performance associated with ultra large scale integration (ULSI) semiconductor device wiring are difficult to satisfy in terms of providing submicron-sized, low resistance-capacitance (RC) metallization patterns. This is particularly applicable when the submicron features, such as vias, contact areas, lines, trenches, and other shaped openings or recesses have high aspect ratios (depth-to-width) due to miniaturization. Conventional semiconductor devices typically comprise a semiconductor substrate, usually a doped monocrystalline silicon (Si), and plurality of sequentially formed interlayer dielectrics and electrically conductive patterns. An integrated circuit is formed therefrom containing a plurality of patterns of conductive lines separated by inter-wiring spacings. Typically, the conductive patterns of vertically spaced metallization layers are electrically connected by vertically oriented conductive plugs filling via holes formed in the interlayer dielectric layer separating the metallization layers, while other conductive plugs filling contact holes establish electrical contact with active device regions, such as a source/drain region of a transistor, formed in or on a semiconductor substrate. Conductive lines formed in trench-like openings typically extend substantially parallel to the semiconductor substrate. Semiconductor devices of such type according to current technology may comprise five or more levels of metallization to satisfy device geometry and micro-miniaturization requirements.

A commonly employed method for forming conductive plugs for electrically interconnecting vertically spaced metallization layers is known as “damascene”-type processing. Generally, this processing involves forming an opening (or via) in the dielectric interlayer, which will subsequently separate the vertically spaced metallization layers. The via is typically formed using conventional lithographic and etching techniques. After the via is formed, the via is filled with conductive material, such as tungsten or copper, using conventional techniques. Excess conductive material on the surface of the dielectric interlayer is then typically removed by chemical mechanical planarization (CMP).

High performance microprocessor applications require rapid speed of semiconductor circuitry, and the integrated circuit speed varies inversely with resistance and capacitance of the interconnection pattern. As integrated circuits become more complex and feature sizes and spacings become smaller, the integrated circuit speed becomes less dependent upon the transistor itself and more dependent upon the interconnection pattern. If the interconnection node is routed over a considerable distance, e.g., hundreds of microns or more, as in submicron technologies, the interconnection capacitance limits the circuit node capacitance loading and, hence, the circuit speed. As integration density increases and feature size decreases, in accordance with submicron design rules, the rejection rate due to integrated circuit speed delays significantly reduces manufacturing throughput and increases manufacturing costs.

One way to increase the circuit speed is to reduce the resistance of a conductive pattern. Aluminum is conventionally employed because it is relatively inexpensive, exhibits low resistivity, and is relatively easy to etch. However, as the size for openings for vias/contacts and trenches is scaled down to the submicron ranges, step coverage problems result from the use of aluminum. Poor step coverage causes high current density and enhanced electromigration. Moreover, low dielectric constant polyamide material, when employed as dielectric interlayers, create moisture/bias reliability problems when in contact with aluminum, and these problems have decreased the reliability of interconnections formed between various metallization layers.

Copper (Cu) and Cu-based alloys are particularly attractive for use in VLSI and ULSI semiconductor devices, which require multi-level metallization layers. Copper and copper-based alloy metallization systems have very low resistivities, which are significantly lower than tungsten and even lower than those of previously preferred systems utilizing aluminum and its alloys. Additionally, copper has a higher resistance to electromigration. Furthermore, copper and its alloys enjoy a considerable cost advantage over a number of other conductive materials, notably silver and gold. Also, in contrast to aluminum and refractory-type metals, copper and its alloys can be readily deposited at low temperatures formed by well-known (wet) plating techniques, such as electroless and electroplating techniques, at deposition rates fully compatible with requirements of manufacturing throughput.

Copper damascene interconnects, especially dual damascene interconnects, often experience via issues such as via voiding and weak interfaces between the barrier and the copper at the bottom of the via. As the via size becomes smaller and the via aspect ratio becomes larger, the issues with vias become increasingly significant. As a result of these issues, reliability problems can arise. One of these issues is electromigration (EM), which has been defined as the transport of metal atoms by momentum exchanged between the electrons, moving under the influence of a field, and metal ions. As shown in the schematic diagram of FIG. 1, electrons flow from the via toward the upper metal in so-called V1M2 type electromigration (EM) structures. Under the force of electron wind, copper will diffuse along the direction of the electron flow and leave a void in the upper metal close to the via or inside the via. When via voiding is present and/or the via barrier-copper interface is weak, it becomes easier to generate the electromigration voids and reduce the activation energy (Ea) of V1M2 type structures. A lower activation energy value translates into a shorter device lifetime.

Common approaches to eliminating via issues focus on the barrier/seed thickness, deposition temperatures, plating chemistry, waveform, etc. As the via aspect ratio becomes larger, and the use of dual damascene arrangements increase, the problems become particularly acute. FIG. 2 depicts a dual damascene arrangement after a copper seed layer has been deposited. The arrangement includes a first metallization layer 10 on which a barrier layer 11 is provided. Dielectric layer 12 is formed on the barrier layer 11. An etch stop layer 14, such as silicon nitride, for example, is formed on the dielectric layer 12. A second dielectric layer 16 is on the etch stop layer 14. A recess 18 is created by etching in the dielectric layers 12 and 16. The recess 18 includes a via hole 20 in communication with a trench 22. The etching can take place in one or more etching steps. A copper seed layer 24 is deposited, by physical vapor deposition (PVD) for example. A barrier layer may also be provided within the recess to prevent diffusion of the copper into the surrounding dielectric layers 12, 16.

The high aspect ratios of the dual damascene technology require a very thin (e.g., A) seed layer 24. As depicted in FIG. 3, a copper fill 30 is provided through an electrochemical plating (ECP) process to create a via 26 and line 28. However, due to the thinness of the seed layer 24, and the acidic plating chemistry, the seed layer 24 may be attacked by the acidic plating chemistry as the vias are filled and the pulse-reverse wave form is initiated. The end result is the formation of voids, such as void 32, at the bottom of the via 26. Such a void 32 is deleterious to electromigration performance and increases the via contact resistance.

There is a need for a method of forming a copper interconnect that allows the copper interconnect to be formed without the creation of voids at the bottom of a via, even with vias having high aspect ratios, such as those found in dual damascene arrangements, for example.

### SUMMARY OF THE INVENTION

This and other needs are met by embodiments of the present invention which provide a method of forming a copper interconnect comprising the steps of forming a recess in a dielectric layer and depositing a seed layer in the recess. The seed layer comprises Cu-x % Sn where x is between 0.1 and 0.5. The method also includes filling the recess with copper to form the copper interconnect. By depositing a seed layer that includes an alloy of Sn, as in certain embodiments of the invention, the presence of the Sn in the seed layer increases the resistance of the seed layer to attack by the acidic plating chemistry. Therefore, the fill is improved and via voids is not observed. The overall result is improved electromigration performance, reduced via resistance and improved product speed.

The earlier stated needs are met by other embodiments of the present invention which provide a method of forming a copper interconnect comprising the steps of depositing an alloy seed layer in a recess in a dielectric layer, the alloy seed layer comprising Cu-x % y, where x is between about 0.1 and about 0.5, and y is an element that causes the alloy seed layer to have a greater resistance to attack by electrochemical plating chemistry than a pure copper seed layer. The recess is then filled with copper to form the copper interconnect.

The earlier stated needs are also met by other embodiments of the present invention which provide a copper interconnect arrangement comprising a dielectric layer and a recess in the dielectric layer. A copper alloy seed layer is in the recess, the copper alloy seed layer having a greater resistance to acidic plating chemistry than a pure copper seed layer. A copper fill in the recess forms the copper interconnect.

The foregoing and other features, aspects and advantages of the present invention will become more apparent from the following detailed description of the present invention when taken in conjunction with the accompanying drawings.

### BRIEF DESCRIPTION OF THE DRAWINGS

FIG. 1 is schematic cross-section of a portion of a metal interconnect arrangement in accordance with the prior art to depict a concern regarding electromigration.

FIG. 2 shows a prior art interconnect arrangement prior to the filling of the recess with a copper fill.

FIG. 3 shows the arrangement of FIG. 2 after the copper fill process has been performed, with a void caused by attack of the copper seed layer by the plating chemistry.

FIG. 4 shows a copper interconnect arrangement constructed in accordance with an embodiment of the present invention, during one stage of the interconnect formation process.

FIG. 5 shows the structure of FIG. 4, following the deposition of an alloy seed layer in accordance with embodiments of the present invention.

FIG. 6 shows the structure of FIG. 5 after the copper fill process has been performed in accordance with embodiments of the present invention.

FIG. 7 depicts the structure of FIG. 6 following planarization to create the copper interconnect.

### DETAILED DESCRIPTION OF THE INVENTION

The present invention addresses and solves problems related to via integrity in copper interconnect formations. In particular, the present invention achieves this, in part, by providing a copper alloy seed layer in the recess, such as in a dual damascene recess. The copper seed layer, which may be Cu-0.3% Sn, for example, provides a greater resistance to the acidic plating chemistry than pure copper seed layer. This prevents voids from forming at the bottom of the via hole during the plating when the copper fill and the pulse-reverse waveform is initiated. Since the void formation is prevented, there is improved electromigration performance, reduced via resistance and improved product speed.

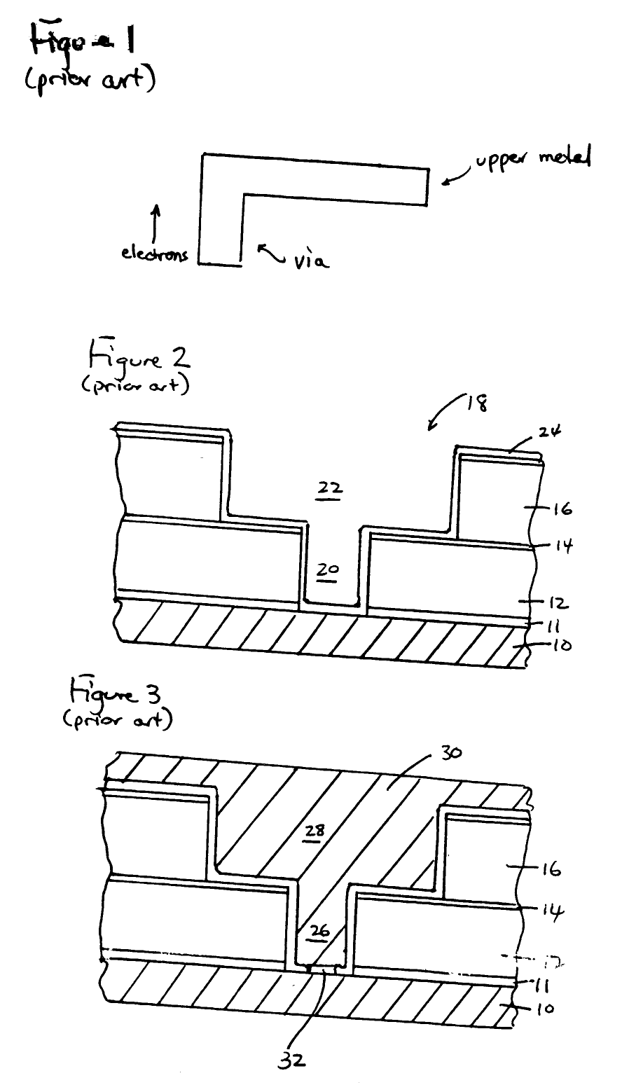

FIG. 4 shows the structure of a copper interconnect formation in accordance with embodiments of the present invention, during one step of the processing. Similar to FIG. 2, the structure of FIG. 4 has a first metallization layer 40 on which a barrier layer 42 is provided. Dielectric layer 44, made of low k dielectric material, for example, or other dielectric material, is formed on the barrier layer 42. Etch stop layer 46, made of silicon nitride, silicon carbide, silicon oxynitride, etc., is provided on the first dielectric layer 44. A second dielectric layer 48 is provided on the etch stop layer 46. This may be made of the same dielectric material as in the first dielectric layer 44, or other type dielectric material. However, presently low k dielectric material is preferred due to the lowering of the overall capacitance. The formation includes a recess 50 having a via hole 52 and a trench hole 54. This may be formed by conventional etching steps.

The structure of FIG. 4 is exemplary only, as other arrangements may be employed, such as having no etch stop layer between the first and second dielectric layers 44, 48, which can be achieved by employing etch stop layers responsive to different etchant chemistries.

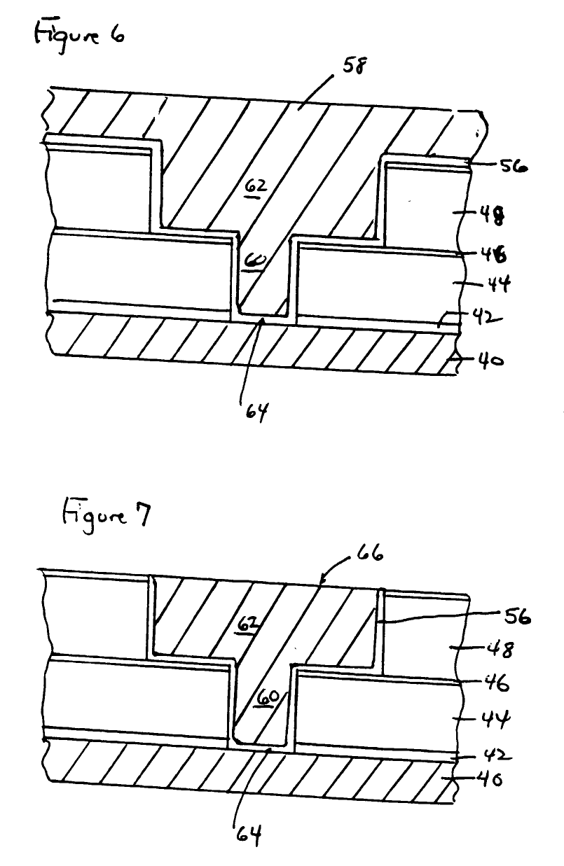

FIG. 5 depicts the structure of FIG. 4 after a copper alloy seed layer 56 has been deposited within the recess 50. The seed layer 56 is very thin, due to the high aspect ratio demanded by the dual damascene structure and overall shrinking dimensions. For example, the thickness of the copper alloy seed layer 56 is between about 400 Å and about 1500 Å.

The copper alloy seed layer 56 includes an alloy element, such as Sn, that acts to increase the resistance of the seed layer 56 to the acidic plating chemistry that will subsequently be employed in the copper fill process. The percentage of Sn in the copper alloy seed layer 56 may be between about 0.1 to about 0.5%, with 0.3% being preferred. The Cu-0.3% Sn copper alloy seed layer 56 may be deposited by conventional technology, such as physical vapor deposition (PVD).

Although Sn is described as being the alloy element in the copper alloy seed layer 56, the invention is not limited to Sn as the alloy element. Other alloy elements, such as Pd, C, Ca, Mg, Al, and Hf may be employed without departing from the scope of the present invention, and still other elements, at long as they sufficiently improve the resistance of the copper alloy seed layer to the acidic plating chemistry.

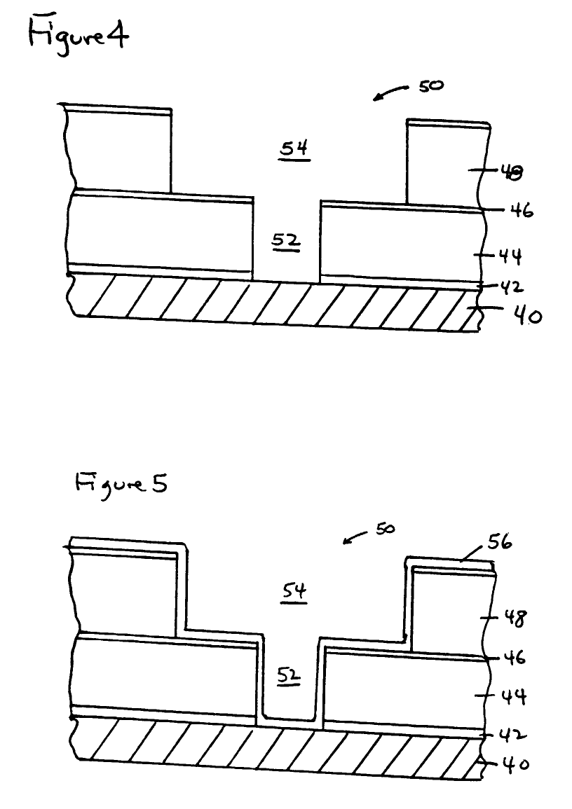

In FIG. 6, the copper fill 58 has been provided by an electrochemical plating (ECP) process, for example, to create a via 60 interconnect with a line 62. In comparison to FIG. 3, it can be seen that there is no void at the bottom 64 of the via 60, unlike the void 32 created at the bottom of the via 26 in prior art FIG. 3. The void is prevented by the copper alloy seed layer 56 used in the present invention to increase resistance of the seed layer to the acidic plating chemistry. Thus, although the seed layer 56 is relatively thin, and the dual damascene via hole 52 has a severe aspect ratio, attack of the thinner seed layer 56 by the plating chemistry as the via is filled in as the pulse-reverse wave form is initiated is avoided.

FIG. 7 depicts the structure of FIG. 6 after planarization, such as chemical mechanical polishing, has been performed to planarize the top surface 66 to create the formed copper interconnect. Since a void at the bottom 64 of the via 60 has been prevented by the use of the copper alloy seed layer 56 in accordance with the present invention, the copper interconnect of the via 60 and the copper line 62 exhibits improved electromigration performance, a reduced via resistance and improved product speed.

The present invention has been described in relation to a dual damascene arrangement since the aspect ratio in dual damascene arrangements are more severe. The present invention is also applicable to single inlaid structures, although improvement in electromigration performance of the copper interconnect in single inlaid structures is not as great as in a dual inlaid structure. This is believed to be because the via in single inlaid structures is normally completely surrounded by barrier material and the via dimensions are well below the critical length (the Blech length) for electromigration. Hence, the via issues do not normally affect the electromigration performance in single inlaid structures. For example, wafers having a copper alloy seed layer, such as the Cu-0.3% Sn layer used in the dual damascene structure of FIG. 7, exhibit a similar activation energy for single inlaid structures is as those wafers employing pure copper seed layers. This suggest that the alloying of 0.3% Sn in copper seed layers does not substantially improve the electromigration performance of copper in single inlaid structures. However, the invention is still applicable to single damascene structures, although not showing the same amount of improvement as in dual damascene structures.

Although the present invention has been described and illustrated in detail, it is to be clearly understood that the same is by way of illustration and example, and is not to be taken by way of limitation, the scope of the present invention being limited only by the terms of the appended claims.

What is claimed is:

1. A method of forming a copper interconnect, comprising the steps of:
forming a recess in a dielectric layer;
depositing a seed layer in the recess, the seed layer comprising Cu-x % Sn, where x is between 0.1 and 0.5; and
filling the recess with copper to form the copper interconnect.

2. The method of claim 1, wherein the recess includes a via hole and a trench hole in communication with the via hole.

3. The method of claim 2, wherein the copper interconnect forms a line and a via integrally coupled to the line.

4. The method of claim 1, wherein the recess is a dual damascene recess, including a via hole and a trench hole in communication with the via hole.

5. The method of claim 4, wherein the copper interconnect is a dual damascene structure, such that the step of filling the recess includes filling the via hole and the trench hole in a single filling step to form a copper interconnect having an integral via and line.

6. The method of claim 1, wherein the seed layer is deposited to a thickness between about 400 Å and about 1500 Å.

7. A method of forming a copper interconnect, comprising the steps of:
depositing an alloy seed layer in a recess in a dielectric layer, the alloy seed layer comprising Cu-x % y, where x is between about 0.1 and about 0.5, and y is an element that causes the alloy seed layer to have a greater resistance to attack by electrochemical plating chemistry than a pure copper seed layer;
filling the recess with copper to form the copper interconnect.

8. The method of claim 7, wherein the element is selected from one of: Sn, Pd, C, Ca, Mg, Al, and Hf.

9. The method of claim 8, wherein the element is Sn.

10. The method of claim 9, wherein y is approximately 0.3%.

11. The method of claim 10, wherein the recess is a dual damascene recess, including a via hole and a trench hole in communication with the via hole.

12. The method of claim 11, wherein the copper interconnect is a dual damascene structure, such that the step of filling the recess includes filing the via hole and the trench hole in a single filling step to form a copper interconnect having an integral via and line.

13. The method of claim 12, wherein the step of filling the recess includes electrochemically plating copper in the recess.

14. A copper interconnect arrangement, comprising:
a dielectric layer;
a recess in the dielectric layer;
a copper alloy seed layer in the recess, the copper alloy seed layer having a greater resistance to acidic plating chemistry than a pure copper seed layer; and
a copper fill in the recess forming the copper interconnect.

15. The arrangement of claim 14, wherein the copper alloy seed layer comprises Cu-x % y, where x is a value between about 0.1 and about 0.5, and y is an element selected from one of: Sn, Pd, C, Ca, Mg, Al, and Hf.

16. The arrangement of claim 15, wherein the element is Sn.

17. The arrangement of claim 16, wherein the recess is a dual damascene recess, including a via hole and a trench hole in communication with the via hole.

18. The method of claim 17, wherein the copper interconnect is a dual damascene structure with an integral via and line.

19. The arrangement of claim 18, wherein the copper alloy seed layer is between about 400 Å and about 1500 Å thick.
